(19) United States
(12) Patent Application Publication
(10) Pub. No.: US 2019/0189465 A1
(43) Pub. Date: Jun. 20, 2019

(54) METHODS AND APPARATUS FOR PHYSICAL VAPOR DEPOSITION

(71) Applicant: APPLIED MATERIALS, INC., Santa Clara, CA (US)

(72) Inventors: KEITH A. MILLER, MOUNTAIN VIEW, CA (US); BENCHERKI MEBARKI, SANTA CLARA, CA (US); JOUNG JOO LEE, SAN JOSE, CA (US); XIANMIN TANG, SAN JOSE, CA (US)

(21) Appl. No.: 16/222,005

(22) Filed: Dec. 17, 2018

Related U.S. Application Data
(60) Provisional application No. 62/641,007, filed on Mar. 9, 2018.
(60) Provisional application No. 62/607,179, filed on Dec. 18, 2017.

(51) Int. Cl. H01L 21/3213; H01L 21/285; H01L 21/768; C23C 14/56; C23C 14/34; H01J 37/34; H01L 21/683

(52) U.S. Cl. CPC H01L 21/32136; H01L 21/2855; H01L 21/76804; H01L 21/76807; H01L 21/683; C23C 14/568; C23C 14/34; H01J 37/3402; H01L 21/76814

(57) ABSTRACT

Methods and apparatus for physical vapor deposition are provided herein. In some embodiments, an apparatus for physical vapor deposition (PVD) includes: a linear PVD source to provide a stream of material flux comprising material to be deposited on a substrate; and a substrate support having a support surface to support the substrate at a non-perpendicular angle to the stream of material flux, wherein at least one of the substrate support or the linear PVD source are movable in a direction parallel to a plane of the support surface of the substrate support sufficiently to cause the stream of material flux to move completely over a surface of the substrate, when disposed on the substrate support during operation.

### CROSS-REFERENCE TO RELATED APPLICATIONS

This application claims benefit of U.S. provisional patent application Ser. No. 62/641,007, filed Mar. 9, 2018 and U.S. provisional patent application Ser. No. 62/607,179, filed Dec. 18, 2017, each of which are herein incorporated by reference in their entirety.

### FIELD

Embodiments of the present disclosure generally relate to substrate processing equipment, and more particularly, to methods and apparatus for depositing materials via physical vapor deposition.

### BACKGROUND

The semiconductor processing industry generally continues to strive for increased uniformity of layers deposited on substrates. For example, with shrinking circuit sizes leading to higher integration of circuits per unit area of the substrate, increased uniformity is generally seen as desired, or required in some applications, in order to maintain satisfactory yields and reduce the cost of fabrication. Various technologies have been developed to deposit layers on substrates in a cost-effective and uniform manner, such as chemical vapor deposition (CVD) or physical vapor deposition (PVD).

However, the inventor has observed that with the drive to produce equipment to deposit more uniformly, certain applications may not be adequately served where purposeful deposition is required that is not symmetric or uniform with respect to the given structures being fabricated on a substrate.

Accordingly, the inventor has provided improved methods and apparatus for depositing materials via physical vapor deposition.

### SUMMARY

Methods and apparatus for physical vapor deposition are provided herein. In accordance with at least some embodiments, there is provided an apparatus for physical vapor deposition (PVD). The apparatus includes a linear PVD source to provide a stream of material flux comprising material to be deposited on a substrate; and a substrate support having a support surface to support the substrate at a non-perpendicular angle to the stream of material flux, wherein at least one of the substrate support or the linear PVD source are movable in a direction parallel to a plane of the support surface of the substrate support sufficiently to cause the stream of material flux to move completely over a surface of the substrate, when disposed on the substrate support during operation.

In accordance with at least some embodiments, there is provided an apparatus for physical vapor deposition (PVD). The apparatus includes a first linear PVD source to provide a first stream of material flux comprising a first material to be deposited at a first non-perpendicular angle on a substrate; a second linear PVD source disposed non-parallel relative to the first linear PVD source to provide a second stream of material flux comprising a second material to be deposited at a second non-perpendicular angle on the substrate; anda substrate support configured to support the substrate, wherein at least one of the substrate support, the first linear PVD source, or the second linear PVD source are movable with respect to each other sufficiently to cause the first stream and the second stream of material flux to move completely over a surface of the substrate during operation.

In accordance with at least some embodiments, there is provided a method for physical vapor deposition (PVD). The method includes supporting, using a substrate support, a substrate at a non-perpendicular angle to a linear PVD source; providing, from the linear PVD source, a stream of material flux comprising material to be deposited on the substrate; and moving at least one of the substrate support or the linear PVD source in a direction parallel to a plane of a support surface of the substrate support sufficiently to cause the stream of material flux to move completely over a surface of the substrate.

Other and further embodiments of the present invention are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIGS. 1A-1B are schematic side and top views, respectively, of an apparatus for physical vapor deposition in accordance with at least some embodiments of the present disclosure.

FIG. 2A is a schematic side view of a feature having a layer of material deposited thereon in accordance with at least some embodiments of the present disclosure.

FIG. 2B is a schematic side view of a substrate having a plurality of features having a layer of material deposited thereon, as depicted in FIG. 2A, in accordance with at least some embodiments of the present disclosure.

FIG. 2C is a schematic side view of a feature having a layer of material deposited thereon in accordance with at least some embodiments of the present disclosure.

FIG. 2D is a schematic side view of a substrate having a plurality of features having a layer of material deposited thereon, as depicted in FIG. 2C, in accordance with at least some embodiments of the present disclosure.

FIGS. 3A-3B are two dimensional and three dimensional schematic side views of an apparatus for physical vapor deposition in accordance with at least some embodiments of the present disclosure.

FIGS. 3C-3D respectively depict schematic top and isometric cross-sectional views of a substrate support and deposition structure of an apparatus for physical vapor deposition in accordance with at least some embodiments of the present disclosure.

FIG. 4 is a schematic side view of an apparatus for physical vapor deposition in accordance with at least some embodiments of the present disclosure.

FIGS. 5A-5B are schematic side and top views, respectively, of an apparatus for physical vapor deposition in accordance with at least some embodiments of the present disclosure.

FIG. 6 is a schematic side view of an apparatus for physical vapor deposition illustrating material deposition angles in accordance with at least some embodiments of the present disclosure.

FIG. 7 is a schematic side view of an apparatus for physical vapor deposition illustrating material deposition angles in accordance with at least some embodiments of the present disclosure.

FIG. 8 is a schematic side view of a portion of an apparatus for physical vapor deposition illustrating material deposition angles in accordance with at least some embodiments of the present disclosure.

FIG. 9 depicts schematic top and side views of an apparatus for physical vapor deposition illustrating material deposition angles in accordance with at least some embodiments of the present disclosure.

FIG. 10 depicts schematic top and side views of an apparatus for physical vapor deposition illustrating material deposition angles in accordance with at least some embodiments of the present disclosure.

FIG. 11 is a schematic side view of an apparatus for physical vapor deposition in accordance with at least some embodiments of the present disclosure.

FIG. 12 is a schematic side view of an apparatus for physical vapor deposition in accordance with at least some embodiments of the present disclosure.

FIG. 13 is a flowchart of a method for physical vapor deposition using the apparatus described herein in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods and apparatus for physical vapor deposition (PVD) are provided herein. Embodiments of the disclosed methods and apparatus advantageously enable uniform angular deposition of materials on a substrate. In such applications, deposited materials are asymmetric or angular with respect to a given feature on a substrate, but can be relatively uniform within all features across the substrate. Embodiments of the disclosed methods and apparatus advantageously enable new applications or opportunities for selective PVD of materials, thus further enabling new markets and capabilities.

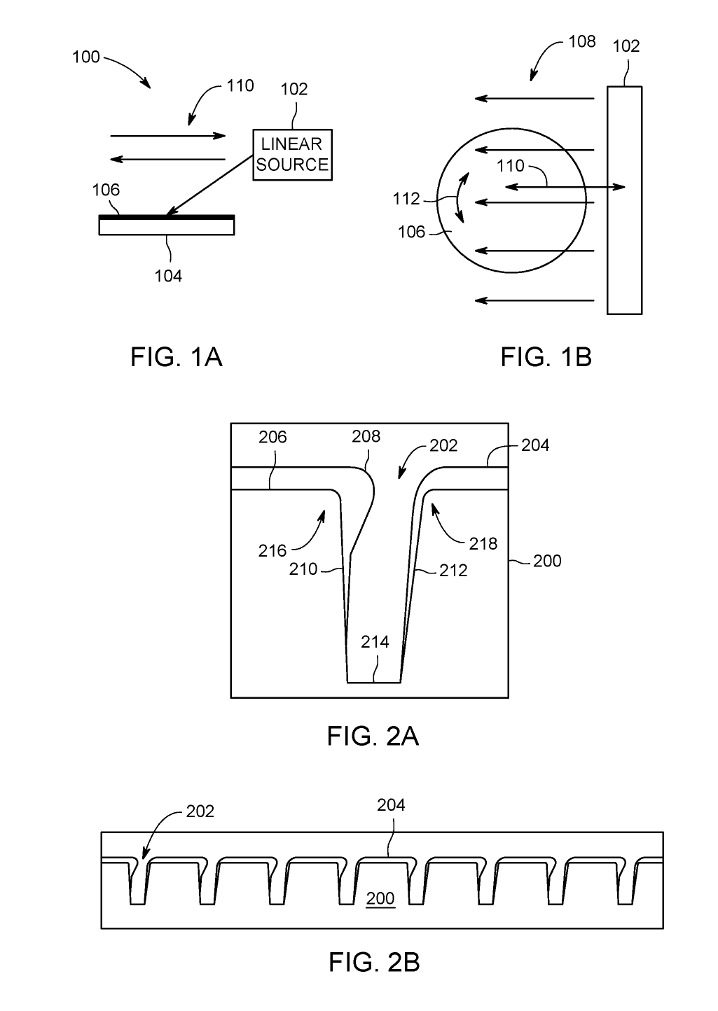

FIGS. 1A-1B are schematic side and top views, respectively, of an apparatus 100 for PVD in accordance with at least some embodiments of the present disclosure. Specifically, FIGS. 1A-1B schematically depict an apparatus 100 for PVD of materials on a substrate 106 at an angle to the generally planar surface of the substrate 106. The apparatus 100 generally includes a linear PVD source 102 and a substrate support 104 for supporting the substrate 106. The linear PVD source 102 is configured to provide a directed stream of material flux (stream 108 as depicted in FIGS. 1A-1B) from the source toward the substrate support 104 (and any substrate 106 disposed on the substrate support 104). The substrate support 104 has a support surface to support the substrate 106 such that a working surface of the substrate 106 to be deposited on is exposed to the directed stream 108 of material flux. The stream 108 of material flux provided by the linear PVD source has a width greater than that of the substrate support 104 (and any substrate 106 disposed on the substrate support 104). The stream 108 of material flux has a linear elongate axis corresponding to the width of the stream 108 of material flux. The substrate support 104 and the linear PVD source 102 are configured to move linearly with respect to each other, as indicated by arrows 110. The relative motion can be accomplished by moving either or both of the linear PVD source 102 or the substrate support 104. Optionally, the substrate support 104 may additionally be configured to rotate (for example, within the plane of the support surface), as indicated by arrows 112.

The linear PVD source 102 includes target material to be sputter deposited on the substrate 106. In some embodiments, the target material can be, for example, a metal, such as titanium, or the like, suitable for depositing titanium (Ti) or titanium nitride (TiN) on the substrate 106. In some embodiments, the target material can be, for example, silicon, or a silicon-containing compound, suitable for depositing silicon (Si), silicon nitride (SiN), silicon oxynitride (SiON), or the like on the substrate 106. Other materials may suitably be used as well in accordance with the teachings provided herein. The linear PVD source 102 further includes, or is coupled to, a power source (not shown) to provide suitable power for forming a plasma proximate the target material and for sputtering atoms off of the target material. The power source can be either or both of a DC or an RF power source.

Unlike an ion beam or other ion source, the linear PVD source 102 is configured to provide mostly neutrals and few ions of the target material. As such, a plasma may be formed having a sufficiently low density to avoid ionizing too many of the sputtered atoms of target material. For example, for a 300 mm diameter wafer as the substrate 106, about 1 to about 40 kW of DC or RF power may be provided. The power or power density applied can be scaled for other size substrates. In addition, other parameters may be controlled to assist in providing mostly neutrals in the stream 108 of material flux. For example, the pressure may be controlled to be sufficiently low so that the mean free path is longer than the general dimensions of an opening of the linear PVD source 102 through which the stream 108 of material flux passes toward the substrate support 104 (as discussed in more detail below). In some embodiments, the pressure may be controlled to be about 0.5 to about 5 millitorr.

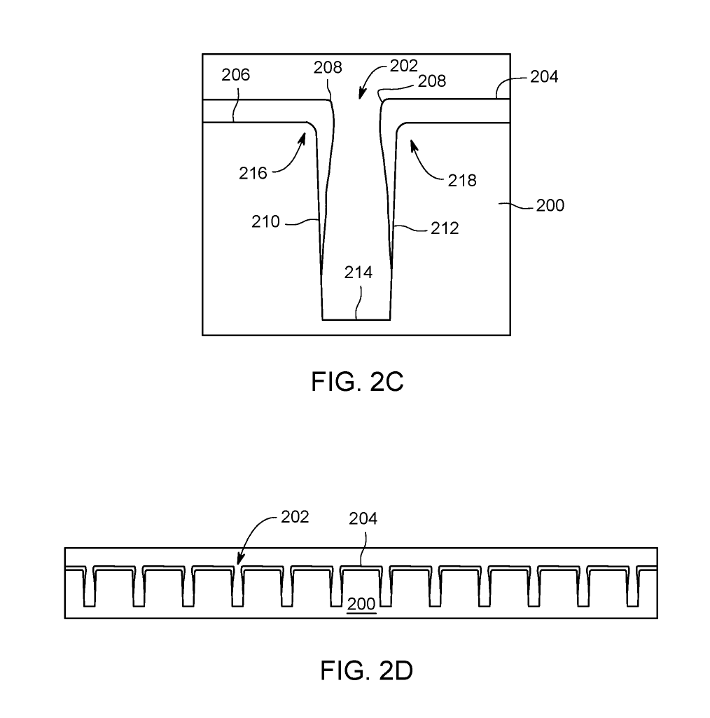

The methods and embodiments disclosed herein advantageously enable deposition of materials with a shaped profile, or in particular, with an asymmetric profile with respect to a given feature on a substrate, while maintaining overall deposition and shape uniformity across all features on a substrate. For example, FIG. 2A depicts a schematic side view of a substrate 200 including a feature 202 having a layer of material 204 deposited thereon in accordance with at least some embodiments of the present disclosure. The feature 202 can be a trench, a via, or dual damascene feature, or the like. In addition, the feature 202 can protrude from the substrate rather than extend into the substrate. The material 204 is deposited not just atop a top surface 206 of the substrate 200 (e.g., the field region), but also within or along at least portions of the feature 202 as well. However, the material 204 is deposited to a greater thickness on a first side 210 of the feature 202 as compared to an opposing second side 212 of the feature (as depicted by portion 208 of material). In some embodiments, and depending upon the incoming angle of the stream 108 of material flux, material can be deposited on a bottom 214 of the feature 202. In some embodiments, and as depicted in FIG. 2A, little or no material 204 is deposited on a bottom 214 of the feature 202. In some embodiments, additional material 204 is deposited particularly near an upper corner 216 of the first side 210 of the feature 202, as compared to an opposite upper corner 218 of the second side 212 of the feature 202.

As shown in FIG. 2B, which is a schematic side view of a substrate having a plurality of features having a layer of material 204 deposited thereon in accordance with at least some embodiments of the present disclosure, the material 204 is deposited relatively uniformly across a plurality of features 202 formed in the substrate 200. As shown in FIG. 2B, the shape of the deposited material 204 is substantially uniform from feature to feature across the substrate 200, but is asymmetric within any given feature 202. Thus, embodiments in accordance with the present disclosure advantageously provide controlled/uniform angular deposition of the material 204 on the substrate 200 with a substantially uniform amount of the material 204 deposited on a field region of the substrate 200.

In some embodiments, for example where the substrate support 104 is configured to rotate in addition to moving linearly with respect to the linear PVD source 102, different profiles of material 204 deposition can be provided. For example, FIG. 2C depicts a schematic side view of a substrate 200 including feature 202 having a layer of material 204 deposited thereon in accordance with at least some embodiments of the present disclosure. As described above with respect to FIGS. 2A-2B, the material 204 is deposited not just atop a top surface 206 of the substrate 200 (e.g., the field region), but also within or along at least portions of the feature 202 as well. However, in embodiments consistent with FIG. 2C, the material 204 is deposited to a greater thickness on both the first side 210 of the feature 202 as well as the opposing second side 212 of the feature 202 (as depicted by portion 208 of material) as compared to the bottom 214 of the feature 202. In some embodiments, and depending upon the incoming angle of the stream 108 of material flux, the amount of materials deposited on lower portions of the sidewall (e.g., the first side 210 and the second side 212) and the bottom 214 of the feature 202 can be controlled. However, as depicted in FIG. 2C, little or no material is deposited on the bottom 214 of the feature 202 (as well as on the lower portion of the sidewalls proximate the bottom 214).

As shown in FIG. 2D, which is a schematic side view of a substrate having a plurality of features having a layer of material deposited thereon in accordance with at least some embodiments of the present disclosure, the material 204 is deposited relatively uniformly across the plurality of features 202 formed in the substrate 200. As shown in FIG. 2D, the shape of the deposited material 204 is substantially uniform from feature to feature across the substrate 200, but with a controlled material profile within any given feature 202. Thus, embodiments in accordance with the present disclosure advantageously provide controlled/uniform angular deposition of material on a substrate with a substantially uniform amount of material deposited on a field region of the substrate 200.

Although the above description of FIGS. 2A-2D refer to the feature 202 having sides (e.g., the first side 210 and the second side 212), the feature 202 can be circular (such as a via). In such cases where the feature 202 is circular, although the feature 202 may have a singular sidewall, the first side 210 and second side 212 can be arbitrarily selected/controlled based upon the orientation of the substrate 200 (e.g, the substrate 106) with respect to the linear axis of movement of the substrate support 104 and direction of the stream 108 of material flux from the linear PVD source 102. Moreover, in embodiments where, for example, the substrate support 104 can rotate, the first side 210 and second side 212 can change, or be blended, dependent upon the orientation of the substrate 106 during processing.

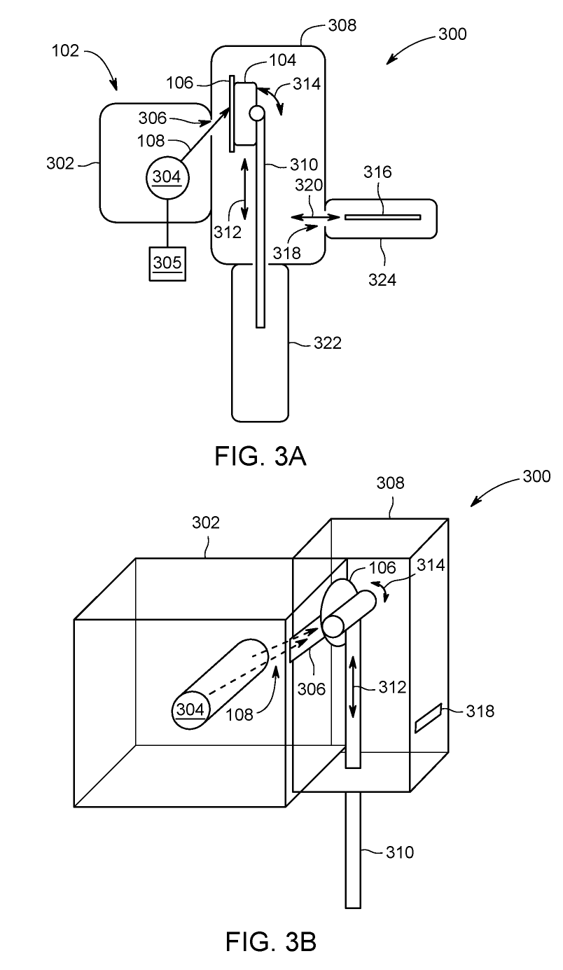

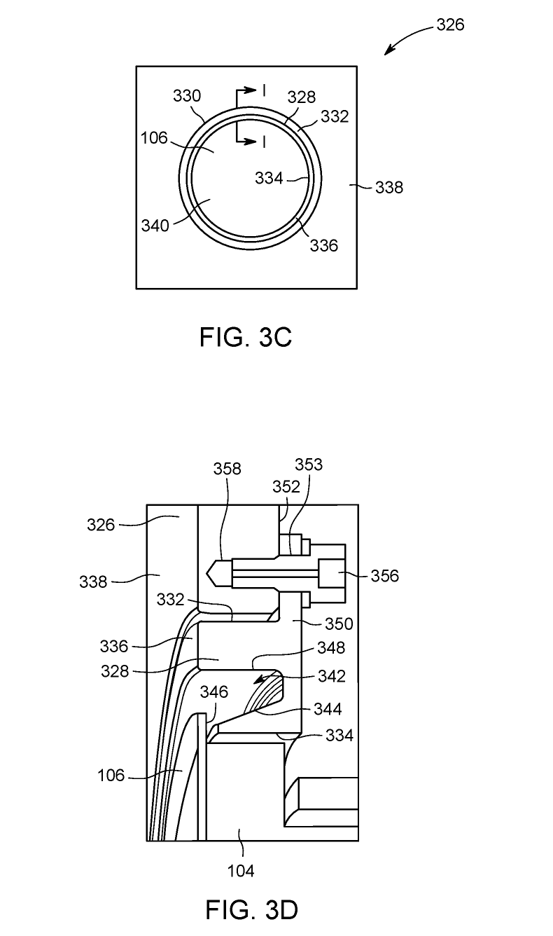

The above apparatus 100 can be implemented in numerous ways, and several non-limiting embodiments are provided herein in FIG. 3A through FIG. 12. While different Figures may discuss different features of the apparatus 100, combinations and variations of these features may be made in keeping with the teachings provided herein. In addition, although the Figures may show an apparatus having a particular orientation (e.g., vertical or horizontal), such orientations are examples and not limiting of the disclosure. For example, any configuration can be rotated or oriented differently than as shown on the page. FIGS. 3A-3B are two dimensional and three dimensional schematic side views of an apparatus 300 for physical vapor deposition in accordance with at least some embodiments of the present disclosure. Certain items shown in FIG. 3A have been removed from FIG. 3B to enhance the clarity of the disclosure. The apparatus 300 is an exemplary implementation of the apparatus 100 and discloses several exemplary features.

As depicted in FIGS. 3A-3B, the linear PVD source may include a chamber or housing 302 having an interior volume. A target 304 of source material to be sputtered is disposed within the housing 302. The target 304 is generally elongate and can be, for example, cylindrical or rectangular. The target 304 size can vary depending upon the size of the substrate 106 and the configuration of the processing chamber (e.g., deposition chamber 308, discussed below). For example, for processing a 300 mm diameter semiconductor wafer, the target 304 can be between about 100 to about 200 mm in width or diameter, and can have a length of about 400 to about 600 mm. The target 304 can be stationary or movable, including rotatable along the elongate axis of the target 304.

The target 304 is coupled to a power source 305. A gas supply (not shown) may be coupled to the interior volume of the housing 302 to provide a gas, such as an inert gas (e.g., argon) or nitrogen (N₂) suitable for forming a plasma within the interior volume when sputtering material from the target 304 (creating the stream 108 of material flux). The housing 302 is coupled to a deposition chamber 308 containing the substrate support 104. A vacuum pump can be coupled to an exhaust port (not shown) in at least one of the housing 302 or the deposition chamber 308 to control the pressure during processing.

An opening 306 couples the interior volumes of the housing 302 and the deposition chamber 308 to allow the stream 108 of material flux to pass from the housing 302 into the deposition chamber 308, and onto the substrate 106. As discussed in more detail below, the position of the opening 306 with respect to the target 304 as well as the dimensions of the opening 306 can be selected or controlled to control the shape and size of the stream 108 of material flux passing though the opening 306 and into the deposition chamber 308. For example, the length of the opening is wide enough to allow the stream 108 of material flux to be wider than the substrate 106. In addition, the width of the opening 306 may be controlled to provide an even deposition rate along the length of the opening 306 (e.g., a wider opening may provide greater deposition uniformity, while a narrower opening may provide increased control over the angle of impingement of the stream 108 of material flux on the substrate 106). In some embodiments, a plurality of magnets may be positioned proximate the target 304 to control the position of the plasma with respect to the target 304 during processing. The deposition process can be tuned by controlling the plasma position (e.g., via the magnet position), and the size and relative position of the opening 306.

The housing 302 can include a liner of suitable material to retain particles deposited on the liner to reduce or eliminate particulate contamination on the substrate 106. The liner can be removable to facilitate cleaning or replacement. Similarly, a liner can be provided to some or all of the deposition chamber 308, for example, at least proximate the opening 306. The housing 302 and the deposition chamber 308 are typically grounded.

In the embodiment depicted in FIGS. 3A-3B the linear PVD source 102 is stationary and the substrate support 104 is configured to linearly move. For example, the substrate support 104 is coupled to a linear slide 310 that can move linearly back and forth along direction of arrow 312 sufficiently within the deposition chamber 308 to allow the stream 108 of material flux to impinge upon desired portions of the substrate 106, such as the entire substrate 106. A position control mechanism 322, such as an actuator, motor, drive, or the like, controls the position of the substrate support 104, for example, via the linear slide 310. The substrate support 104 may be moved linearly along a plane such that the surface of the substrate 106 is maintained at a perpendicular distance of about 1 to about 10 mm from the opening 306. The substrate support 104 can be moved at a rate to control the deposition rate on the substrate 106. Alternatively, or additionally, the substrate support 104 can be coupled to robot linkage (not shown) that is configured to move the substrate support 104 linearly back and forth sufficiently within the deposition chamber 308 to allow the stream 108 of material flux to impinge upon desired portions of the substrate 106, such as the entire substrate 106.

Optionally, the substrate support 104 can also be configured to rotate within the plane of the support surface, such that the substrate 106 disposed on the substrate support 104 can be rotated. A rotation control mechanism, such as an actuator, a motor, a drive, a robot, or the like, controls the rotation of the substrate support 104 independent of the linear position of the substrate support 104. Accordingly, the substrate support 104 can be rotated while the substrate support 104 is also moving linearly through the stream 108 of material flux during operation. Alternatively, the substrate support 104 can be rotated between linear scans of the substrate support 104 through the stream 108 of material flux during operation (e.g., the substrate support 104 can be moved linearly without rotation, and rotated while not moving linearly).

In addition, the substrate support 104 can move to a position for loading and unloading of substrates into and out of the deposition chamber 308. For example, in some embodiments, a transfer chamber 324, such as a load lock, may be coupled to the deposition chamber 308 via a slot or opening 318. A substrate transfer robot 316, or other similar suitable substrate transfer device, can be disposed within the transfer chamber 324 and movable between the transfer chamber 324 and the deposition chamber 308, as indicated by arrows 320, to move substrates into and out of the deposition chamber 308 (and onto and off of the substrate support 104). In embodiments where the substrate support 104 has a different orientation required for deposition and transfer, the substrate support 104 can further be rotatable or otherwise movable, as indicated by arrows 314. For example, in the embodiments depicted in FIGS. 3A-3B, the substrate support 104 can be in a horizontal, and lower, position (in terms of the Figures) when moving substrates between the substrate support 104 and the transfer chamber 324. In addition, the substrate support 104 can be in a vertical, and upper, position (in terms of the Figures) when moving the substrate 106 relative to the stream 108 of material flux to deposit materials atop the substrate 106.

Depending upon the configuration of the substrate support 104, and in particular of the support surface of the substrate support 104 (e.g., vertical, horizontal, or angled), the substrate support 104 may be configured appropriately to retain the substrate 106 during processing. For example, in some embodiments, the substrate 106 may rest on the substrate support 104 via gravity. In some embodiments, the substrate 106 may be secured onto the substrate support 104, for example, via a vacuum chuck, an electrostatic chuck, mechanical clamps, or the like. Substrate guides and alignment structures may also be provided to improve alignment and retention of the substrate 106 on the substrate support 104.

FIGS. 3C-3D respectively depict schematic top and isometric cross-sectional views of a substrate support and deposition structure of an apparatus for physical vapor deposition in accordance with at least some embodiments of the present disclosure. FIG. 3D is an isometric cross-sectional view of the substrate support and deposition structure taken along line I-I in FIG. 3C.

A deposition structure 326 may be disposed around the substrate 106 and the substrate support 104 within the deposition chamber 308. For example, the deposition structure 326 may be coupled to the substrate support 104. In some embodiments, the deposition structure 326 and a front surface of the substrate 106 form a common planar surface. The deposition structure 326 reduces deposits or particles from accumulating on the edge and backside of the substrate 106 during the scanning of the substrate 106. Furthermore, use of the deposition structure 326 reduces deposits or particles from accumulating on the substrate support 104 and hardware and equipment in the vicinity of the substrate support 104. In some embodiments, a voltage source (not shown) may be coupled to a portion of the deposition structure 326 to apply a charge to a portion of the deposition structure 326. In some embodiments, the voltage source may be used to apply a voltage or charge to a removable structure 328 associated with the deposition structure 326. Although the stream 108 of material flux comprises mostly neutrals, applying a charge to the portion of the deposition structure 326 or the removable structure 328 may further reduce deposits or particles that accumulate on the edge and backside of the substrate during the scanning of the substrate 106 due to any ionized particles.

In some embodiments, the deposition structure 326 includes a removable structure 328 disposed in an opening 330 of the deposition structure 326. The removable structure 328 can have a shape that corresponds to the substrate 106. For example, in embodiments where the substrate 106 is a circular substrate, such as a semiconductor wafer, the removable structure 328 is a removable ring structure. As depicted in FIGS. 3C-3D, the substrate 106 is exposed through the opening 330.

The removable structure 328 has an outside edge surface 332 and an inside edge surface 334. A circumference of the inside edge surface 334 is greater than a circumference of the substrate support 104. Furthermore, in some embodiments, the removable structure 328 has an exterior surface 336 aligned with a front surface 338 of the deposition structure 326. Furthermore, in some embodiments, a front surface 340 of the substrate 106 may be aligned with the front surface 338 of the deposition structure 326 and the exterior surface 336 of the removable structure 328. Therefore, in some embodiments, the exterior surface 336 of the removable structure 328, the front surface 338 of the deposition structure 326, and the front surface 340 of the substrate 106 form a planar surface. In some embodiments, the exterior surface 336 is not aligned with the front surface 338 of the deposition structure 326 and/or the front surface 340 of the substrate 106.

As depicted in FIG. 3D, the removable structure 328 includes a groove 342. The groove 342 may be formed in at least a portion of a circumference of the removable structure 328. In some embodiments, the groove 342 is formed in the entire circumference of the removable structure 328. The groove 342 may include an angled surface 344 functional to direct the particles associated with the stream 108 of material flux away from a backside 346 of the substrate 106. Moreover, the angled surface 344 is functional to direct particles associated with the stream 108 of material flux away from the substrate support 104. In some embodiments, particles associated with the stream 108 of material flux may be directed by the angled surface 344 toward a surface 348 associated with the groove 342. The groove 342 may be formed having a shallower or deeper depth than shown in FIG. 3D. Furthermore, while the surface 348 is illustrated as being straight, the surface 348 may alternatively be formed at an angle similar to the angled surface 344.

The removable structure 328 can include a ledge 350. The ledge 350 may be in contact with a backside 352 of the deposition structure 326. In some embodiments, the ledge 350 is removably press fit against the deposition structure 326, on the backside 352 of the deposition structure 326.

In some embodiments, the ledge 350 is coupled to the deposition structure 326, on the backside 352 of the deposition structure 326. For example, the removable structure 328 may include one or more through holes 353. In some embodiments, a plurality of through holes 353 are disposed in the ledge 350. The plurality of through holes 353 may receive a retainer element 356, such as a fastener, screw, or the like. Each of the retainer elements 356 may be received by a hole 358 in the deposition structure 326. Therefore, the deposition structure 326 may include a plurality of the holes 358. In another embodiment, the holes 358 may be through holes so that the retainer elements 356 may be inserted from the front surface 338 of the deposition structure 326 and retainably attached to the ledge 350 using a nut, fastener or threads.

The substrate plane structure having the removable structure 328, e.g., a removable ring, is advantageously straightforward to maintain. Specifically, advantageously, rather than removing the entire substrate plane structure when preventive maintenance is required, the removable structure 328 can be removed to complete the required preventative maintenance. Furthermore, because the substrate plane structure and the removable structure 328 pieces advantageously provide a modular unit, the costs associated with maintaining and replacing the modular unit may be advantageously reduced compared to maintaining and replacing conventional substrate plane structures formed as one contiguous unit. In addition, advantageously, the removable structure 328, for example, may be made from different materials compared to the remainder of the substrate plan structure. For example, use of particular material types for the removable structure 328 may advantageously mitigate accumulation of deposits and particles on the edge of the substrate 106 or a wafer.

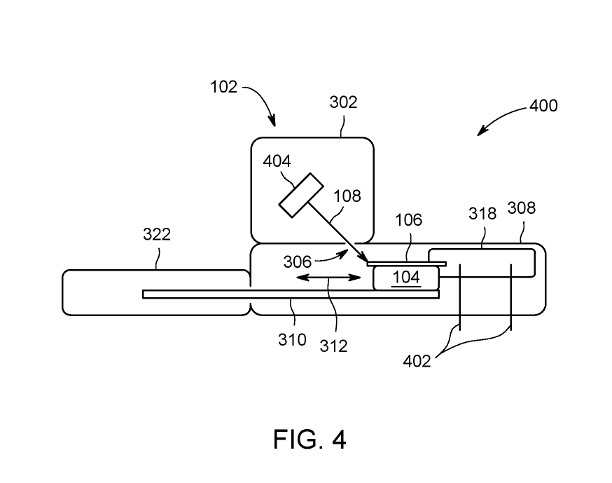

FIG. 4 is a schematic side view of an apparatus 400 for physical vapor deposition in accordance with at least some embodiments of the present disclosure. The apparatus 400 is an exemplary implementation of the apparatus 100 and discloses several exemplary features. The apparatus 400 is similar to and operates in similar fashion as the apparatus 300 described above except that the orientation of the substrate 106 remains constant relative to the deposition and loading/unloading positions, as compared to the orthogonal relative positions in the apparatus 300. In addition, in the orientation of the page, FIGS. 3A-3B depicts a vertically configured system (e.g., the substrate support 104 moves vertically), and FIG. 4 depicts a horizontally configured system (e.g., the substrate support 104 moves horizontally).

As depicted in FIG. 4, a plurality of lift pins 402 can be provided proximate the opening 318 to facilitate transferring the substrate 106 between the substrate support 104 and a substrate transfer robot (e.g., as discussed above with respect to FIGS. 3A-B).

In addition, the target can have a different configuration than the cylindrical target 304 depicted in other Figures. Specifically, target 404 can be a rectangular target having, for example, a planar rectangular face of target material to be sputtered. The aforementioned target configuration can also be used in any of the other embodiments disclosed herein.

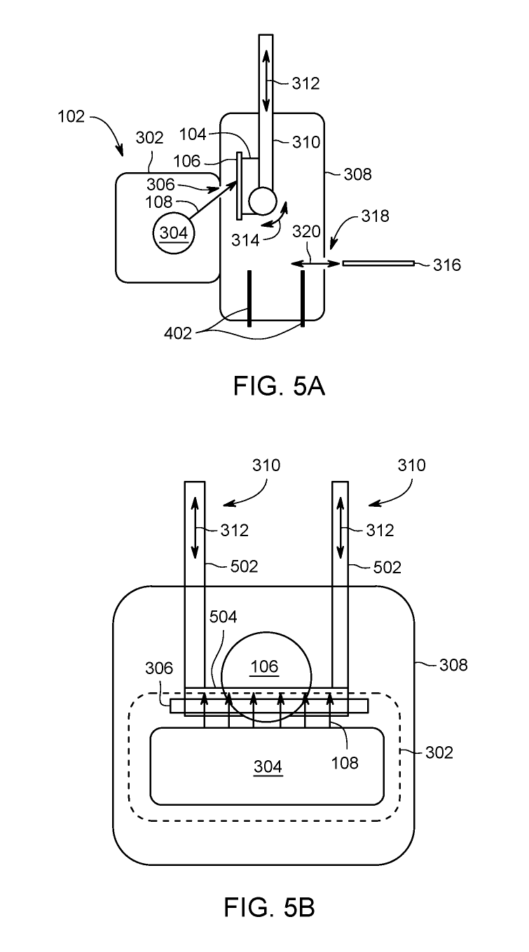

FIGS. 5A-5B are schematic side and top views, respectively, of an apparatus for physical vapor deposition in accordance with at least some embodiments of the present disclosure. The apparatus is an exemplary implementation of the apparatus 100 and discloses several exemplary features. The apparatus of FIGS. 5A-5B is similar to and operates in similar fashion as the apparatus 300 described above except that the linear slide 310 (and position control mechanism 322, not shown) extend from the top of the deposition chamber 308, rather than from the bottom.

In addition, as depicted in FIG. 5B, the linear slide 310 can include a plurality of linear slide members 502. Each linear slide member 502 can be coupled to the substrate support 104 at a first end, for example, via a cross member 504. An opposing end of the linear slide members 502 can be coupled to the position control mechanism 322 to facilitate control of the substrate support 104.

In embodiments of a PVD apparatus as disclosed herein, the general angle of incidence of the stream 108 of material flux can be controlled or selected to facilitate a desired deposition profile of material on the substrate. In addition, the general shape of the stream 108 of material flux can be controlled or selected to control the deposition profile of material deposited on the substrate. In some embodiments, material can be deposited on a top surface of the substrate and a first sidewall of a feature on the substrate (e.g., substantially as depicted in FIGS. 2A-2D). In some embodiments, depending upon the deposition angle, material can further be deposited on a bottom surface of the feature 202. In some embodiments, depending upon the deposition angle, material can further be deposited on an opposing sidewall surface of the feature 202, with greater deposition on a first sidewall (e.g., first side 210) as compared to the opposing sidewall (e.g., second side 212) of the feature 202.

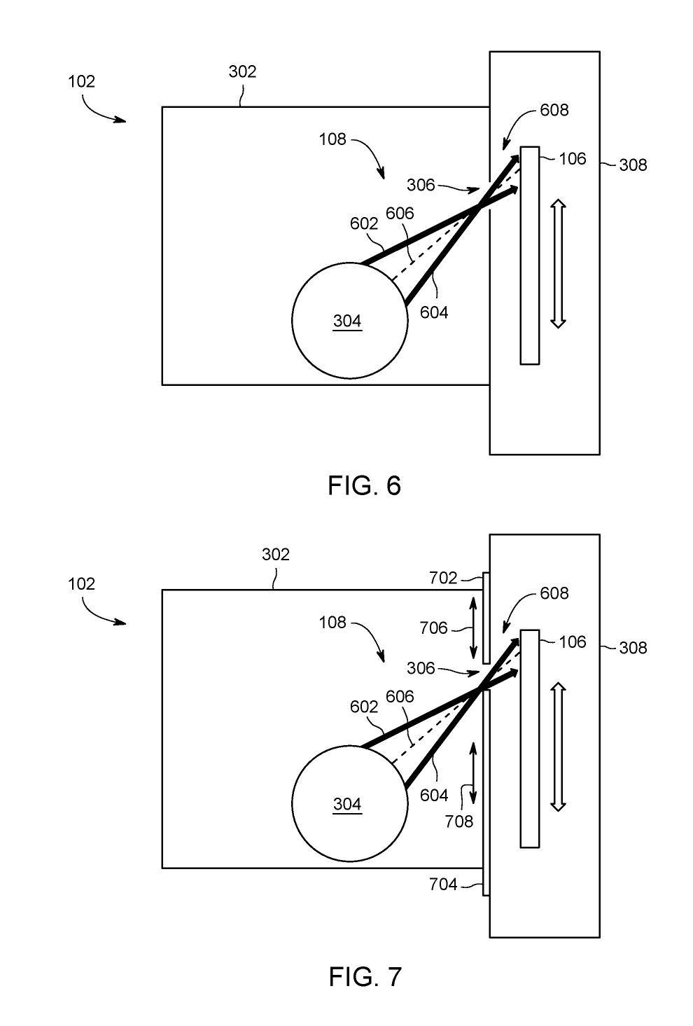

For example, FIG. 6 is a schematic side view of an apparatus for physical vapor deposition illustrating material deposition angles in accordance with at least some embodiments of the present disclosure. The position of the target 304 within the housing 302 with respect to the opening 306 coupling the housing 302 to the deposition chamber 308 defines a general angle of incidence of the stream 108, as depicted by dashed line 606, in a plane orthogonal to the length of the opening 306 (e.g., in the plane of the page, where the opening 306 runs in a direction into and out of the page). However, the general angle of incidence is not the angle of incidence of all particles in the stream 108 of material flux, since the particles can come from different locations on the target and can generally travel through the opening along a line of sight from the location on the target where the particle originated. For example, arrows 602 and 604 show typical boundaries of the stream 108 of material flux from the target that can pass through the opening. Particles travelling in other directions will not pass through the opening 306 and will be retained within the housing 302, and a portion 608 of the stream 108 of material flux that passes through the opening 306 impinges upon the substrate 106 (see FIGS. 6 and 7).

In some embodiments, at least one of the width of the opening or the position of the opening can be controlled to allow altering the relative position of the opening and the target within the housing. For example, FIG. 7 is a schematic side view of an apparatus for physical vapor deposition illustrating material deposition angles in accordance with at least some embodiments of the present disclosure. In some embodiments, at least one movable shutter is provided (two movable shutters 702, 704 shown in FIG. 7) on the housing 302 and/or the deposition chamber 308. Shutters 702, 704 are movable linearly as indicated by arrows 706, 708. By control of one or both shutters 702, 704, the width of the opening 306 and/or the relative position of the opening 306 can be controlled. For example, moving one shutter, e.g., 702, with respect to the other shutter, e.g., 704, can change the width of the opening 306. Alternatively, moving both shutters 702, 704 together can change the position of the opening 306 with respect to the target 304 without altering the width of the opening 306. Alternatively, moving both shutters 702, 704 to different locations can change both the position and the width of the opening 306.

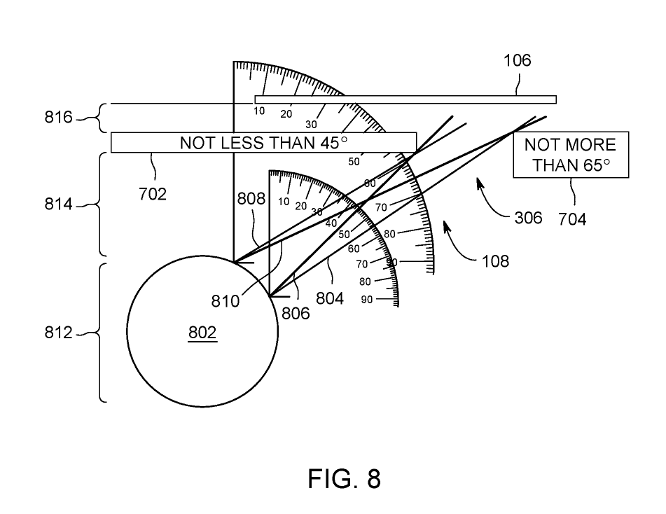

As an example, FIG. 8 is a schematic side view of a portion of an apparatus for physical vapor deposition illustrating material deposition angles in accordance with at least some embodiments of the present disclosure. As shown in FIG. 8, to control the size of the stream 108 of material flux, in addition to the angle of incidence, several parameters can be predetermined, selected, or controlled. For example, a diameter 812 or width of a target 802 can be predetermined, selected, or controlled (e.g., the substrate can have a given diameter). In addition, a first working distance 814 from the target 802 to the sidewall of the housing 302 containing the opening 306 (or to the shutters 702, 704), can be predetermined, selected, or controlled. A second working distance 816 from the opening 306 to the substrate 106 can also be predetermined, selected, or controlled. Lastly, the size of the opening 306 can be predetermined, selected, or controlled. Taking these parameters into account, the minimum and maximum angles of incidence can be predetermined, selected, or controlled as shown in FIG. 8. In addition, in embodiments with one or more movable shutters 702, 704, the shutters 702, 704 may be controlled to adjust the minimum and/or maximum angles of incidence of particles from the stream 108 of material flux.

For example, with a given target diameter 812 of target 802, working distance 814, and second working distance 816, the size of the opening 306 can be set to control a width of the stream 108 of material flux that passes through the opening 306 and impinges upon the substrate 106. For example, the opening 306 (and other parameters discussed above) can be set to control the minimum and maximum angles of incidence of material from the stream 108 of material flux. For example, lines 806 and 804 represent possible paths of material from a first portion of the target 802 that can pass through the opening 306. Lines 808 and 810 represent possible paths of material from a second portion of the target 802 that can pass through the opening 306. The first and second portions of the target 802 represent the maximum spread of materials with line of sight paths to the opening 306. The overlap of paths of materials that can travel via line of sight through the opening 306 are bounded by lines 806 and 810, which represent the minimum and maximum angles of incidence of material from the stream 108 of material flux that can pass through the opening 306 and deposit on the substrate 106. The angles of 45 degrees and 65 degrees are illustrative. For example, the angle of impingement may generally range between about 10 to about 65 degrees, or more.

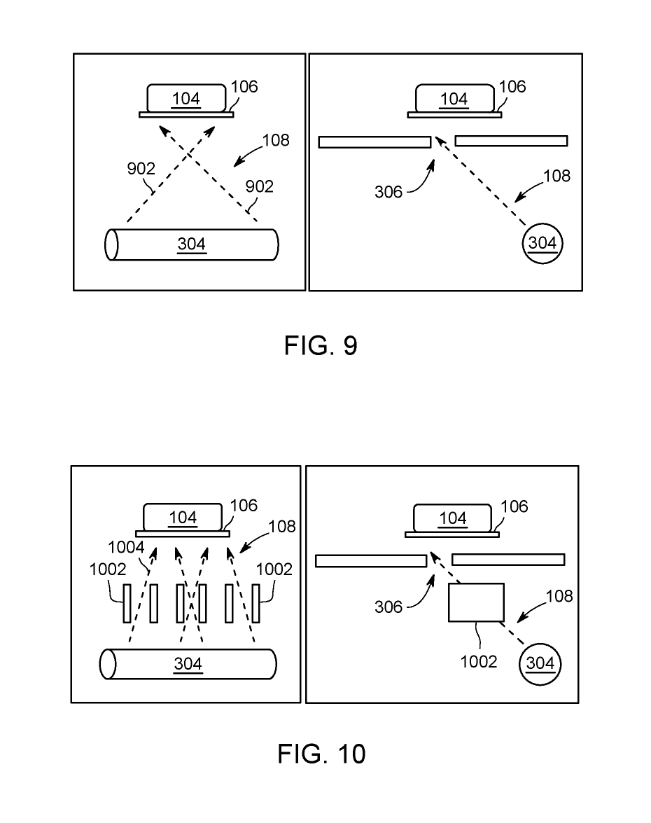

The above discussion with respect to FIGS. 6-8 refer to the shape and angles of incidence of materials from the stream 108 of material flux along planes orthogonal to the axial length of the opening 306 (e.g., side views of the stream 108 of material flux). FIG. 9 depicts schematic top and side views of an apparatus for physical vapor deposition illustrating top and side view of material deposition angles in accordance with at least some embodiments of the present disclosure. As depicted in FIG. 9, right panel, a side view of the stream 108 of material flux is shown, which corresponds to FIGS. 6-8 above. FIG. 9, left panel, depicts a top view showing the stream 108 of material flux from a top view, parallel to the axial length of the target 304 (and opening 306), referred to herein as in a lateral direction (e.g., side to side along the axial length of the target). As shown in the top view of FIG. 9, left panel, the angles 902 of incidence of material from the stream 108 of material flux can vary greatly and also are not controlled as the angles are along the side dimensions discussed above.

In some embodiments, the lateral angles of incidence can also be controlled. For example, FIG. 10 depicts schematic top and side views of an apparatus for physical vapor deposition illustrating material deposition angles 1004 in accordance with at least some embodiments of the present disclosure. The teachings of FIG. 10 can be incorporated in any of the embodiments disclosed herein. As depicted in FIG. 10, physical structure such as baffles, or collimator 1002, can be interposed between the target 304 and the opening 306 such that the stream 108 of material flux travels through the structure (e.g., collimator 1002). Any materials with an angle to great to pass through the structure will be blocked from passing through the opening 306, thus limiting the permitted angular range of materials passing through the opening 306.

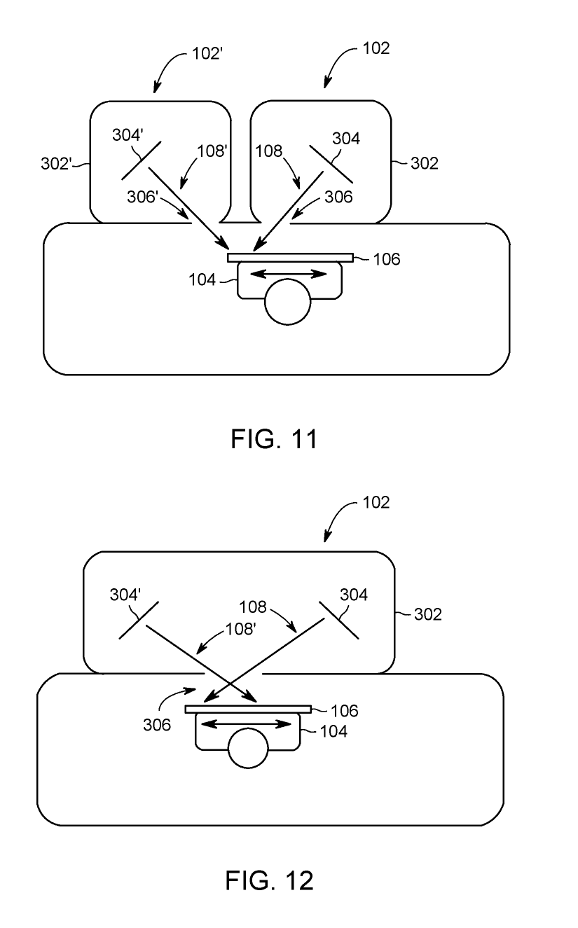

Combinations and variations of the above embodiments include apparatus having more than one target to facilitate deposition at multiple angles. For example, FIG. 11 is a schematic side view of an apparatus for physical vapor deposition in accordance with at least some embodiments of the present disclosure. As depicted in FIG. 11, two linear PVD sources 102, 102′ in respective housing 302, 302′ may be provided, such that targets 304, 304′ can have respective streams 108, 108′ of material flux that are separately, e.g., simultaneously or sequentially, directed through respective openings 306, 306′ to impinge of the substrate 106. The target materials can be the same material or different materials. In addition, process gases provided to the separate linear PVD sources 102, 102′ can be the same or different. The size of the targets, location of the targets, location and size of the openings, can be independently controlled to independently control the impingement of materials from each stream 108, 108′ of material flux onto the substrate 106.

FIG. 12 is a schematic side view of an apparatus for physical vapor deposition in accordance with at least some embodiments of the present disclosure. FIG. 12 is similar to the embodiment of FIG. 11 except that the two targets 304, 304′ are provided within the same linear PVD source 102.

In each of the embodiments of FIGS. 11-12, the relative angles of the targets 304, 304′, and thus the direction of the streams 108, 108′ of material flux are illustrative and other angles can be chosen independently, including in directions such that the targets 304, 304′ are not parallel to each other.

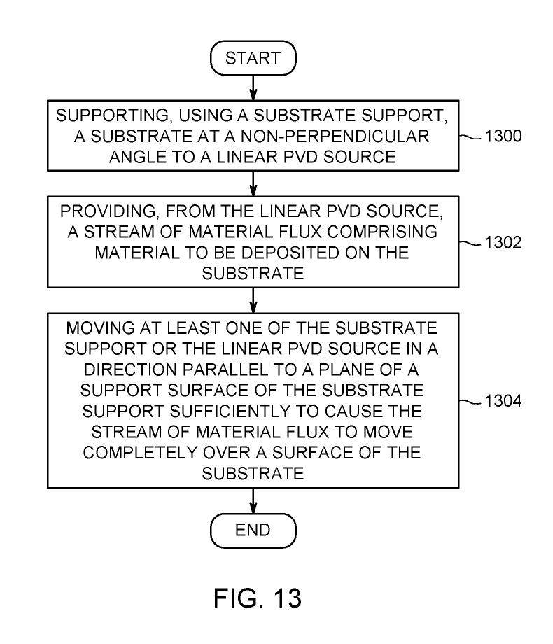

FIG. 13 is a flowchart of a method for PVD using the apparatus described herein in accordance with at least some embodiments of the present disclosure. In operation, a substrate (e.g., the substrates 106, 200) is disposed on the support surface of the substrate support 104 at 1300, and a stream of material flux (e.g., stream 108) can be provided from a linear PVD source (e.g., the linear PVD sources 102, 102′) at 1302. For the example, in some embodiments the substrate can be supported at a non-perpendicular angle to the linear PVD source. Alternatively or additionally, the linear PVD source can provide the stream 108 of material flux at an the non-perpendicular angle, in a manner as described above. The stream of material flux passes into the deposition chamber 308 through the opening 306 between the linear PVD source and the deposition chamber 308. Optionally, the range of angles of travel of the material within the elongate dimension of the stream 108 of material flux can be limited (e.g., as disclosed in FIG. 10).

The substrate support 104, at 1304, can be moved linearly from a first position (for example, where the stream 108 of material flux is proximate the first side 210 of the substrate 200), through the stream 108 of material flux to a second position (for example, where the stream 108 of material flux is proximate the second side 212 of the substrate 200 opposite the first side 210). Alternatively, or additionally, the linear PVD source can be moved in a similar manner as the substrate support 104, e.g., from the first position to the second position.

The first position can position the substrate completely out of the stream 108 of material flux, or at least a portion of the stream 108 of material flux. The second position can also position the substrate completely out of the stream 108 of material flux, or at least a portion of the stream 108 of material flux. The amount of deposition of material on the substrate depends upon the deposition rate and the rate of speed of the linear movement of the substrate through the stream 108 of material flux. The substrate can pass through the stream 108 of material flux once (e.g., move from the first position to the second position once) or multiple times (e.g., move from the first position to the second position, then move from the second position to the first position, etc.) in order to deposit a desired thickness of material on the substrate. Optionally, the substrate can be rotated between passes (e.g., after reaching the first position or the second position at the end of linear movement) or while passing through the stream 108 of material flux (e.g., at the same time as the linear movement from the first position to the second position).

In embodiments where two streams 108, 108′ of material flux are provided (e.g., as shown in FIGS. 11-12), the streams 108, 108′ can be alternated or provided simultaneously. In addition, the orientation of the substrate can be rotationally fixed or variable. For example, in some embodiments, the two streams 108, 108′ of material flux can alternately provide the same material or different materials to be deposited asymmetrically on the substrate as shown in FIGS. 2A-2B. The substrate can be rotationally fixed while the first stream (e.g., the stream 108) of material flux is provided in a first pass through the first stream of material flux. The substrate can then be rotated 180 degrees and subsequently be rotationally fixed while the second stream (e.g., the stream 108′) of material flux is provided in a first pass through the second stream of material flux. If desired, after completion of the first pass through the second stream of material flux, the substrate can again be rotated 180 degrees and then held rotationally fixed in a second pass through the first stream of material flux. The rotation of the substrate and passes through either the first or the second streams of material flux can continue until a desired thickness of material is provided. In cases where the first and second streams of material flux provide different materials to be deposited, the rate of movement of the substrate support can be the same or different when passing through the first stream of material flux as compared to passing through the second stream of material flux.

In some embodiments, the substrate can be rotated continuously while passing through the first or the second stream of material flux (e.g., at the same time as the linear movement from the first position to the second position or from the second position to the first position) to achieve a deposition profile similar to that shown in FIGS. 2C-2D.

While the foregoing is directed to embodiments of the present disclosure, other and further embodiments of the disclosure may be devised without departing from the basic scope thereof.

1. An apparatus for physical vapor deposition (PVD), comprising:
a linear PVD source to provide a stream of material flux comprising material to be deposited on a substrate; and
a substrate support having a support surface to support the substrate at a non-perpendicular angle to the stream of material flux, wherein at least one of the substrate support or the linear PVD source are movable in a direction parallel to a plane of the support surface of the substrate support sufficiently to cause the stream of material flux to move completely over a surface of the substrate, when disposed on the substrate support during operation.

2. The apparatus of claim 1, wherein the apparatus comprises a housing coupled to a deposition chamber, and an opening couples interior volumes of the housing and the deposition chamber to allow the stream of material flux to pass from the housing into the deposition chamber and onto the surface of the substrate.

3. The apparatus of claim 2, wherein at least one of a width of the opening or a position of the opening is adjustable.

4. The apparatus of claim 3, wherein at least one movable shutter is provided to control the at least one of the width of the opening or the position of the opening.

5. The apparatus of claim 2, wherein an angle of impingement that the stream of material flux passes through the opening ranges from about 10 degrees to about 65 degrees.

6. The apparatus of claim 1, wherein the substrate support is rotatable within the plane of the support surface.

7. The apparatus of claim 1, wherein the linear PVD source further comprises a second linear PVD source configured to provide a second stream of material flux comprising material to be deposited on a substrate.

8. The apparatus of claim 7, wherein the stream of material flux and the second stream of material flux passes are configured to impinge on the substrate at different angles.

9. An apparatus for physical vapor deposition (PVD), comprising:
a first linear PVD source to provide a first stream of material flux comprising a first material to be deposited at a first non-perpendicular angle on a substrate;
a second linear PVD source disposed non-parallel relative to the first linear PVD source to provide a second stream of material flux comprising a second material to be deposited at a second non-perpendicular angle on the substrate; and
a substrate support configured to support the substrate,
wherein at least one of the substrate support, the first linear PVD source, or the second linear PVD source are movable with respect to each other sufficiently to cause the first stream and the second stream of material flux to move completely over a surface of the substrate during operation.

10. The apparatus of claim 9, wherein the apparatus comprises a housing coupled to a deposition chamber, and an opening that couples interior volumes of the housing and the deposition chamber to allow the first stream and the second stream of material flux to pass from the housing into the deposition chamber and onto the surface of the substrate during operation.

11. The apparatus of claim 10, wherein at least one of a width of the opening or a position of the opening is adjustable.

12. The apparatus of claim 11, wherein at least one movable shutter is provided to control the at least one of the width of the opening or the position of the opening.

13. The apparatus of claim 10, wherein an angle of impingement that the first stream of material flux passes through the opening ranges from 10 degrees to about 65 degrees, and wherein an angle of impingement that the second stream of material flux passes through the opening ranges from 10 degrees to about 65 degrees.

14. The apparatus of claim 13, wherein an angle of impingement that the second stream of material flux passes through the opening is different from the angle of impingement that the first stream of material flux passes through the opening.

15. The apparatus of claim 9, wherein the substrate support is rotatable.

16. The apparatus of claim 9, wherein the first material is the same material as the second material.

17. A method for physical vapor deposition (PVD), comprising:
supporting, using a substrate support, a substrate at a non-perpendicular angle to a linear PVD source;
providing, from the linear PVD source, a stream of material flux comprising material to be deposited on the substrate; and
moving at least one of the substrate support or the linear PVD source in a direction parallel to a plane of a support surface of the substrate support sufficiently to cause the stream of material flux to move completely over a surface of the substrate.

18. The method of claim 17, wherein the apparatus comprises a housing coupled to a deposition chamber, and
providing the stream of material flux comprises providing the stream of material flux through an opening that couples interior volumes of the housing and the deposition chamber to allow the stream of material flux to pass from the housing into the deposition chamber and onto the surface of the substrate.

19. The method of claim 18, further comprising controlling at least one of a width of the opening or a position of the opening to alter a relative position of the opening and the material within the housing and to control a deposition rate along a length of the opening and deposition uniformity along the surface of the substrate.

20. The method of claim 19, further comprising moving at least one shutter that is provided on one of the housing or the deposition chamber to control the at least one of the width of the opening or the position of the opening.
